(19) United States
(12) Patent Application Publication
(10) Pub. No.: US 2019/0064061 A1
(43) Pub. Date: Feb. 28, 2019

(54) GAS SENSOR USING VCSEL

(71) Applicant: Innovative Micro Technology, Goleta, CA (US)

(72) Inventor: Christopher S. GUDEMAN, Lompoc, CA (US)

(73) Assignee: Innovative Micro Technology, Goleta, CA (US)

(21) Appl. No.: 16/105,693

(22) Filed: Aug. 20, 2018

Related U.S. Application Data
(60) Provisional application No. 62/550,570, filed on Aug. 26, 2017.

(51) Int. Cl. G01N 21/25; H01S 5/022; H01S 5/00; H01S 5/183; G01N 21/3504

(52) U.S. Cl. CPC G01N 21/255; H01S 5/02248; G01N 2201/0612; H01S 5/183; G01N 21/3504; H01S 5/0071

(57) ABSTRACT

Systems and methods for forming a compact gas sensor include using a lithographically fabricated, reflective and lengthy gas channel formed in at least two substrate to make a relatively long gas channel. A VCSEL radiation source may be coupled to the channel and a photodiode detector to measure the transmitted light.

### CROSS REFERENCE TO RELATED APPLICATIONS

This nonprovisional US Patent Application claims priority to U.S. Provisional Application Ser. No. 62/550570, filed Aug. 25, 2017 and incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to a gas sensing device.

Gas sensors require high sensitivity and high specificity, two factors are often in opposition, since a very sensitive system will likely be sensitive to many gasses. But high sensitivity is extremely important, for example exposure 1 part per million of CO in the atmosphere will cause headaches in 10 minutes and irreversible brain damage 60 minutes.

Chemical receptor systems that provide very high sensitivity to CO, often have a low level sensitivity to CO₂, which is far more abundant. Thus distinguishing between harmful and benign gases is a problem. Chemical receptor systems can become contaminated, which causes a loss in sensitivity and risk to personnel requiring protection.

Gas sensors fall into several categories, based on the detection mechanism that they employ. Generally, these include the following:

Chemical receptors are available for specific capture of the target molecule. Here, a chemical compound is covalently bonded to a substrate, which is part of the sensor. Within the molecular structure of this chemical compound is a functional group of atoms that will link with a specific type of target molecule. If a target molecule attaches to the chemical receptor, a change is recorded in the substrate voltage, current, temperature, conductivity, magnetic moment, optical absorbance or reflection. These signals are often very weak and similar levels of a given signal can arise from a variety of molecular species. This leads to inaccuracies, false positives and false negatives.

Resonant beam structures may determine the mass of the molecule. The resonant beam structure is often used with the chemical receptor. These beams are very low in mass so the attachment of a population of target molecules can significantly affect the mass and thus significantly change the frequency of its fundamental mechanical resonance. The shift in resonant frequency is generally small and the quantity of target molecules and their chemical structure are factors that are difficult to separate. This measurement can thus also lead to incorrect identification. Finally, strongly adhered target molecules can be difficult to desorb following the sensing measurement.

Sensors can combust the target species and measure its exothermicity. Most gaseous molecular species can be oxidized, which means they can be burned or combusted in an oxygen environment, such as air. A few notable exceptions (non-combustible compounds) include O₂, N₂, CO₂, Ar, and H₂O, which are the constituents of air. Therefore, the heat generated during the chemical reaction of combustion is a means of sensing combustible trace impurities in air. In other words, because the dominant constituents of air do not combust, the trace species can more easily be detected without interference by measuring the heat generated. This measurement can be used to identify the impurity. For example, the heat generated during combustion of CO is far less than the heat generated by burning benzene, heptane, or tri-nitro-toluene (TNT), for example. All of the latter, however, have similar heat generation per unit mass of target species. Also the quantity of heat generated is extremely low, making accurate detection difficult. To ignite the target molecules, the system for combustion must operate at very high temperature, thus leading to very short lifetime and poor reliability.

Chemical Field Effect Transistors (Chem-FET). If the gate electrode of a field effect transistor (FET) is replaced by a population of covalently-bonded chemical receptors, the trans-conductance of the FET will change in the presence of molecules that attach to the receptors. Intrinsically the FET provides gain and thus this method can be very sensitive. However, attached target molecules can be difficult to detach following a sensing episode, since high temperature, which can adversely affect the FET, is required to desorb attached molecules. Strongly bonded contaminants can survive even the highest temperatures that can be practically applied in the field of use.

Combinations of the above. Due to the limitations outlined above, it has been found useful to combine those methods into a system. This can greatly reduce the risk of false positive and false negative responses, although the cost and complexity of the system are increased.

All of these share, to some extent, the following draw backs

1) Contamination

2) Probable false readings (inaccuracy)

3) Low sensitivity

4) Low specificity

Accordingly, a new technology is needed for sensing these dangerous compounds in homes, offices and industrial settings. Ideally this technology is small, inexpensive, robust and highly sensitive.

### SUMMARY

Gases are composed of low molecular weight molecules, since only small molecules are gaseous at ambient temperatures. In the gas phase, these small molecules are constantly tumbling and vibrating in highly precise quantum states. The energy levels of these quantum states are extensively cataloged and the transition energies between states are known to an astounding precision of nine significant digits (one part per billion or ppb). These precise transition frequencies can be used to sense and identify gases for applications such as air pollution monitoring, automotive engine performance optimization, industrial chemical synthesis control, automotive passenger compartment CO₂ sensing, home carbon monoxide sensing, fermentation process control, and indoor agriculture.

The device and method described here uses high resolution infrared spectroscopy to detect and identify small gas molecules. The spectrum of thousands of small molecules is well documented. These spectra provide a finger print of each that can be used to unambiguously identify each, with no chance of falsely assigning the measured spectrum.

The gas sensor described here creates a long absorption path by lithographically forming small gas channels in a substrate. Two substrates can be positioned to form a serpentine long path. The channel sides may be coated with a reflective film, for example gold (Au). An emitter, for example a vertical cavity surface emitting laser (VCSEL) diode, may be coupled into the channel, and the radiation transmitted down the channel by reflection off the film. A detector may be provided at the end of the channel.

Accordingly, the gas sensing device may include at least one substrate with at least one cavity formed lithographically therein, and with a reflective film coating sidewalls of the at least one cavity, and wherein the at least one cavity is configured for multiple passes of a ray of light within the cavity, a sample gas filling the lithographically formed cavities; a radiation source coupled to the at least one substrate that launches radiation into the lithographically formed channels, and a detector coupled to the at least one substrate, that detects radiation transmitting the lithographically formed channels.

Within the gas sensing device, the at least one substrate may comprise of at least two substrates with at least one cavity formed on each substrate, and wherein the substrates are arranged such that the cavities partly overlap and form passages that interconnect, to form a longer optical path through the interconnected cavities.

A method is also disclosed, wherein the method may include filling a lithographically formed gas channel with a sample gas, wherein the channel is formed by bonding at least two substrates, wherein the substrates are arranged in a staggered fashion and bonded together to form a longer lithographically formed channel, launching radiation from a VCSEL down the lithographically formed gas channel, and detecting the radiation after transiting the lithographically formed channel.

These and other features and advantages are described in, or are apparent from, the following detailed description.

### BRIEF DESCRIPTION OF THE DRAWINGS

Various exemplary details are described with reference to the accompanying drawings, which however, should not be taken to limit the invention to the specific embodiments shown but are for explanation and understanding only.

FIG. 1 shows a plan view of a first embodiment of the lithographically formed channels with VCSEL source coupled thereto;

FIG. 2 shows a plan view of a second embodiment of the lithographically formed channels with VCSEL source coupled thereto, wherein the channels form a serpentine structure;

FIG. 3 shows a plan view of a third embodiment of the lithographically formed channels with VCSEL source coupled thereto, with the cavities rotated with respect to one another;

FIG. 4 shows a cross sectional view of an embodiment of the lithographically formed channels with VCSEL source coupled thereto, wherein the cavities overlap to form an interconnecting passageway;

FIG. 5 shows a cross sectional view of a fifth embodiment of the lithographically formed channels with VCSEL source coupled thereto, wherein the cavities are formed in an isotropic substrate;

FIG. 6 shows a cross sectional view of a sixth embodiment of the lithographically formed channels with VCSEL source coupled thereto, wherein the cavities are formed in an isotropic substrate;

FIG. 7 shows a cross sectional view of a seventh embodiment of the lithographically formed channels with VCSEL source, wherein the cavity is a single long trench formed in an isotropic substrate; and

FIG. 8 shows a typical infrared spectrum of the atmosphere in the region of the CO2.

It should be understood that the drawings are not necessarily to scale, and that like numbers maybe may refer to like features.

### DETAILED DESCRIPTION

Gases are composed of low molecular weight molecules, since only small molecules are gaseous at ambient temperatures. In the gas phase these small molecules are constantly tumbling in highly precise quantum vibrational and rotational states. The energy levels of these quantum states are extensively cataloged and the transition energies between states are known to an astounding precision of nine significant digits (one part per billion or ppb). These precise transition frequencies can be used terrestrially to sense and identify gases for applications such as air pollution monitoring, automotive engine performance optimization, industrial chemical synthesis control, automotive passenger compartment CO₂ sensing, home carbon monoxide sensing, fermentation process control, and indoor agriculture.

The device and method described here uses high resolution infrared spectroscopy to detect and identify small gas molecules. The spectrum of thousands of small molecules is well documented. These spectra provide a finger print of each that can be used to unambiguously identify each, with no chance of falsely assigning the measured spectrum.

To provide high sensitivity the spectrometer must possess several aspects:
1) A long absorption path, which is created by bonding a plurality of Si wafers, each with numerous KOH etched trenches. These trenches overlap to form an enclosed channel, or waveguide, which is coated with a high reflectance metal such as Au for high infrared transmittance. As a second embodiment, these channels can be made in glass using an isotropic HF etch, followed by a similar Au coating and bond.
2) A bright, tunable, narrow band light source at the spectral region of interest. VCSELs throughout the infrared spectrum are available. This light source must have a bandwidth roughly similar or less than the molecular absorption spacing.
3) A sensitive infrared detector. Numerous semiconductor detector technologies exist today.
4) A digital spectral database that can be quickly compared to the observed spectrum for identification and quantification.

The device and method described here uses high resolution infrared spectroscopy to detect and identify small gas molecules. The spectrum of thousands of small molecules is well documented. These spectra provide a finger print of each that can be used to unambiguously identify each, with no chance of falsely assigning the measured spectrum.

To provide high sensitivity the spectrometer must possess a long absorption path. The long absorption path may be formed lithographically in one or more substrates. The substrates may be lithographically etched to form at least one cavity and with a reflective film coating sidewalls of the at least one cavity. The at least one cavity may be configured for multiple passes of a ray of light within the cavity by reflection of off the sidewalls of the cavity. A plurality of cavities may be formed in two substrates, and the substrates oriented such that the cavities overlap. This may result in an open passageway interconnecting the cavities, such that a ray of light may, through multiple reflections from the sidewalls, leave the VCSEL and ultimately impinge upon the detector.

The path may be created by bonding a plurality of Si wafers, each with numerous KOH etched trenches. As mentioned, these trenches overlap to form an enclosed channel, or waveguide, which is coated with a high reflectance metal such as Au for high infrared transmittance. As a second embodiment, these channels can be made in glass using an isotropic HF etch, followed by a similar Au coating and bond.

Accordingly, the device described here may include a bright, tunable, narrow band light source at the spectral region of interest. VCSELs throughout the infrared spectrum are available. This light source must have a bandwidth roughly similar or less than the molecular absorption spacing. It may also include a sensitive infrared detector. Numerous semiconductor detector technologies exist today. The device may make use of a digital spectral database that can be quickly compared to the observed spectrum for identification and quantification.

The following discussion presents a plurality of exemplary embodiments of the novel gas sensor. The following reference numbers are used in the accompanying figures to refer to the following:

10 VCSEL source

20 gas inlet

30 detector

40-48 lithographically defined cavities

80 ray trace

110 lid wafer

115 gold coating

It should be understood that the designation of “first”, “second”, “upper” and “lower” are arbitrary, that is, the cavity may also be formed on an upper substrate and bonded to a lower substrate, or vice-versa. The terms “wafer” and “substrate” are used interchangeably herein, to refer to a supporting member, generally flat and circular, often of a material such as silicon or glass, as is well known in the art. Finally, the terms “cavity,” “channel” and “trench” are used interchangeably to refer to a depression made by removing material in an area of the substrate.

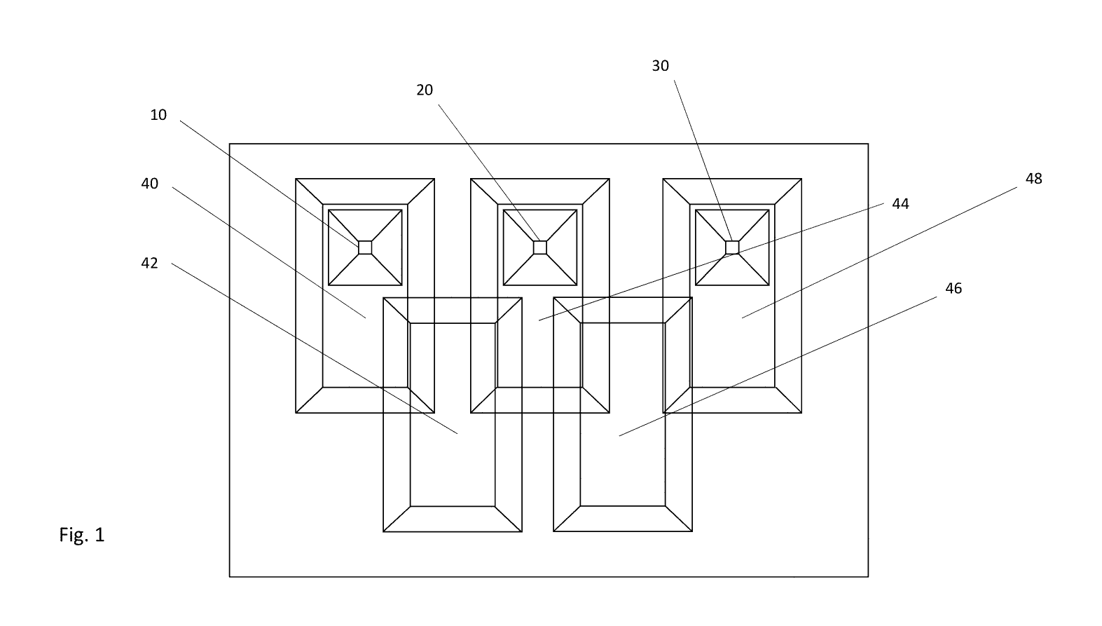

FIG. 1 shows a serpentine waveguide formed by bonding two KOH etched Si wafers, This may be a first embodiment, having generally rectilinear contours. The SI wafers may be offset from one another as shown.

In FIG. 1, 10 is the VCSEL source disposed in a first cavity, which may be a gallium arsenide (GaAs), aluminum gallium arsenide (AlGaAs), and indium gallium arsenide nitride (InGaAsN) component. Such sources have very narrow line widths and can be tuned by adjusting the current or voltage applied to the VCSEL. The VCSEL may emit infrared radiation into a cone of about 30 degrees. A VCSEL typically emits light in the infrared spectrum, and is tunable up to about 20% of its nominal wavelength.

As the term is used herein, a VCSEL refers to a vertical-cavity surface-emitting laser, which is a type of semiconductor laser diode with laserbeam emission perpendicular from the top surface, contrary to conventional edge-emitting semiconductor lasers (also in-plane lasers) which emit from surfaces formed by cleaving the individual chip out of a wafer. VCSEL applications include fiber optic communications, precision sensing, computer mice, laser printers and augmented reality. VCSELS are typically narrow band, and emit into a rather narrow cone compared to diode lasers. VCSELs use epitaxial layers grown on the wafer to create mirrors on the surface with a LED sandwiched in between, perfect for coupling to fibers and for the instant application.

VCSELS can be designed to emit at certain wavelengths, and to be adjustable about that wavelength. In general, the tuning mechanism is heating through current or voltage, which tends to lengthen the wavelength because of thermal expansion of the device. In any case, VCSELS may be designed to emit at about 2300 wavenumbers, which is a spectral range of particular interest in spectroscopy, as discussed below.

As shown in FIG. 1, cavities 40, 44, and 48 may be formed on one substrate 100, and cavities 10, 20, 30, 42, and 46 may be formed on another substrate 200. The larger cavities 40, 44 and 48 may be formed simultaneously or in sequence with the smaller cavities 10, 20 and 30. The smaller cavities 10, 20 and 30 will house the VCSEL source, the gas inlet and detector, respectively. Because the smaller cavities 10, 20 and 30 are always associated with the source, gas inlet and detector, the reference number 10 may refer either to the source, its cavity or both, and reference number 30 may refer to the detector, its cavity, or both. Reference number 20 may refer to the gas inlet, its cavity, and any associated hardware such as valving.

The detector 30 may be any of a number of photo-sensitive devices, such as a diode, microchannel plate, CCD camera, photomultiplier tube, and the like. The detector need only be sensitive to the appropriate range of frequencies and put out a signal in response to the reception of the radiation.

The substrates 100 and 200 may be silicon, and the cavities 40, 44 and 48 may be formed in the substrate 100 by exposing the silicon material to a potassium hydroxide (KOH) etchant. As is well known in the art, the KOH may perform anisotropic etching on the silicon material, such that the <100> plane is etched preferentially, because the <111> plane etches at a much slower rate than the other planes. Thus, a groove, channel or depression will be formed as a result of wet etching of silicon, making an angle of 54.74 between the <100> and the <111> plane. As a result of this anisotropy, the walls of the trench formed by KOH etching may have an incline of about 54 degrees with respect to horizontal. To perform this etching at between 50° C. and 70° C., a KOH solution may be prepared by adding the required amount of deionized water to a standard 45 wt % solution.

The cavities 44 and 48 may be formed simultaneously with cavity 40 in the first substrate 100. Thus, cavities 44 and 48 may also be formed using a KOH anisotropic etch, such that it may also have 54 degree sidewalls. In fact, three similar cavities 40, 44 and 48 may be formed in the first substrate 100 adjacent to one another and simultaneously, by putting a mask on the surface with slotted apertures, and applying a KOH solution to the exposed surface.

The source cavity 10, gas inlet cavity 20 and detector cavity 30 may be formed by KOH etching in the second substrate 200. A gas inlet may be formed as another cavity 20 in the second substrate 200. Similarly, a photodetector 30 may be disposed at the bottom of the this cavity 48.

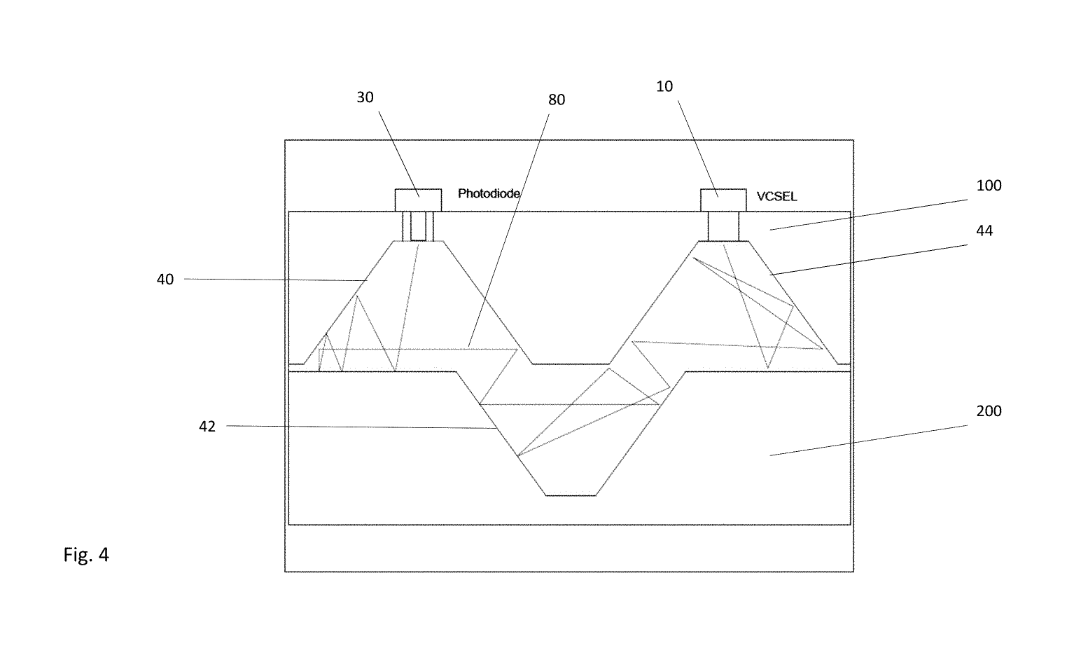

Besides the source, inlet and detector cavities 10, 20 and 30, the two additional larger cavities 42 and 46 may be formed in an opposing substrate 200. Note that the first substrate 100 and the second substrate 200 are not identified in FIG. 1. Because FIG. 1 is a plan view, the two substrates 100 and 200 are not visible in FIG. 1. Please refer to FIG. 4, a cross sectional diagram, to identify substrate 100 and substrate 200 with respect to the etched cavities and their overlap.

Cavities 10, 20, 30, 42 and 46 may also be formed using a KOH anisotropic etch, such that they may also have 54 degree sidewalls. Accordingly, two similar cavities 42 and 46 may be formed in the second substrate 200 and disposed laterally adjacent to one another. Alternatively, cavities 10, 20, 30, 42, and 46 can be formed in the second substrate, while cavities 40 44, and 48 are formed in the first substrate.

Cavities 10, 20, 30, 42, and 46 may all be etched simultaneously with a single masking layer until the etch reaches a depth of approximately 400 microns. At this time, the etch process may be halted and a second mask layer may be applied that masks further etching on cavities 42 and 46. The KOH etch is then resumed until cavities 10, 20 and 30 etch through the entirety of the 500 um substrate. At this time the masking layers may be stripped and the gold is deposited everywhere to enable the Au-Au thermocompression bond.

The starting substrates may be silicon, 500 microns thick for example. The etched cavities 40, 42, 44, 46 and 48 may be about 400 microns deep. The cavities may be about 1 mm to 1 cm in height and about 500 microns in width. It should be understood that these dimensions are exemplary only, and that many other shapes and placements of cavities may be possible, depending on the application.

As mentioned, after formation of the cavities 10-48 in the first and second substrates 100 and 200, each of the substrate surfaces, with their cavities, may be coated with a gold reflective layer. Accordingly, the cavities will have highly reflective 54 degree sidewalls which are also coated with a highly reflective material. The thickness of the gold layer may be about 0.1 microns, simply enough to form a continuous, reflective layer.

The second substrate 200 with two cavities 42 and 46 formed thereon, or alternatively with five cavities 42, 46, 10, 20 and 30, may be placed against the first substrate 100 with three cavities 40, 44 and 48 formed thereon. Cavities 42 and 46 may be shifted laterally with respect to cavities 40, 44 and 48, such that the cavities overlap to an extent, forming passageways that interconnect the cavities, and form a longer path length between emitter 10 and detector 30.

The two substrates may be bonded in this position. A gold-gold thermocompression bond may be convenient in this application, as gold may be deposited uniformly over the surfaces as a reflective layer. Thermocompression bonds are well known in the art, and result when two gold surfaces are pressed together and heated.

The gas inlet 20 may be formed in the first substrate 100 or in the second substrate 200 and be a simple aperture or with a with a valve that can introduce a sample gas to the interconnected cavities. The gas then fills the cavities 10, 30 and 40-48.

The radiation emitted by VCSEL 10 may impinge upon the 54 degree walls of the cavity 40, and be reflected at a large percentage. Accordingly, a ray of light may be reflected off the surfaces of the cavities many times before finally reaching the detector 30. By staggering the cavities 42, 44 of the second substrate 200 with respect to those 40, 44 and 48 of the first substrate 100, a passageway is formed between the cavities. Using this passageway, a ray may trace a path from emitter 10 to detector 30 by undergoing a plurality of reflections off of the 54 degree sidewalls. This configuration of cavities may be referred to herein as interconnected cavities, because a passage is created between the cavities that allows a ray of light to traverse the whole sequence of cavities from source 10 to detector 30 by undergoing many reflections and re-directions and meandering through each cavity in succession, until being absorbed by the detector, 30.

Accordingly, upon emission from the VCSEL source, a ray of light may impinge serially on the walls of each cavity 10, 40, 42, 44, 46, 48 and eventually to detector 30. The path of the light from source 10 to detector 30 may as a result, be rather long, and thus the pathlength through the gas sample input at cavity 20 may be quite long. A long path length is advantageous for absorption spectroscopy, because the gas atoms have many opportunities to absorb the radiation. For absorption spectroscopy such as this device, a long pathlength improves the signal to noise of the measurement.

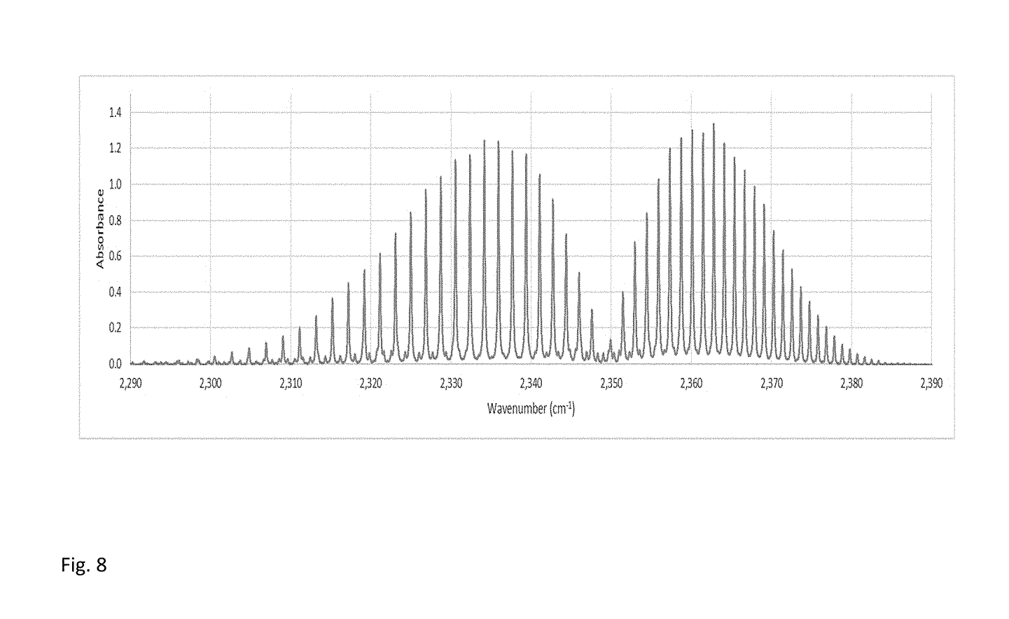

FIG. 8 shows the absorption spectrum of carbon dioxide (CO₂) in the infrared. Each absorption peak corresponds to a quantum mechanical excitation of the CO₂ molecule from a rotational state in the ground vibrational state to a rotational state in the 1^{st} excited vibrational state. Because the CO₂ molecule is so simple, its spectrum is also quite simple. The molecule absorbs the incident light, which in this case is in the infrared, and which induces the transition. This absorbed energy may be re-radiated at a shifted frequency, or it may be transferred to another molecule, such O2 or N2 and be dissipated as heat.

Some energy is removed from the radiation because of absorption by the gas. This occurs at exactly the wavelength of light that matches the energy of the transition. The science of measuring the radiation energy loss as it passes through a sample is known as absorption spectroscopy. The peaks in a spectrum are often referred to as lines due to older spectroscopic methods that used a grating as a monochromator and photographic film as a detector. The light diffracted from the grating would expose a series of lines on the photographic emulsion. Unfortunately, for very high resolution, classical monochromators can be several meters long so that the individual wavelengths can be adequately separated by from each other.

Accordingly, if CO₂ is present in the sample, and the wavelength of light is at an absorption peak, the radiation will be strongly attenuated. Thus the presence of CO₂ can be determined unambiguously.

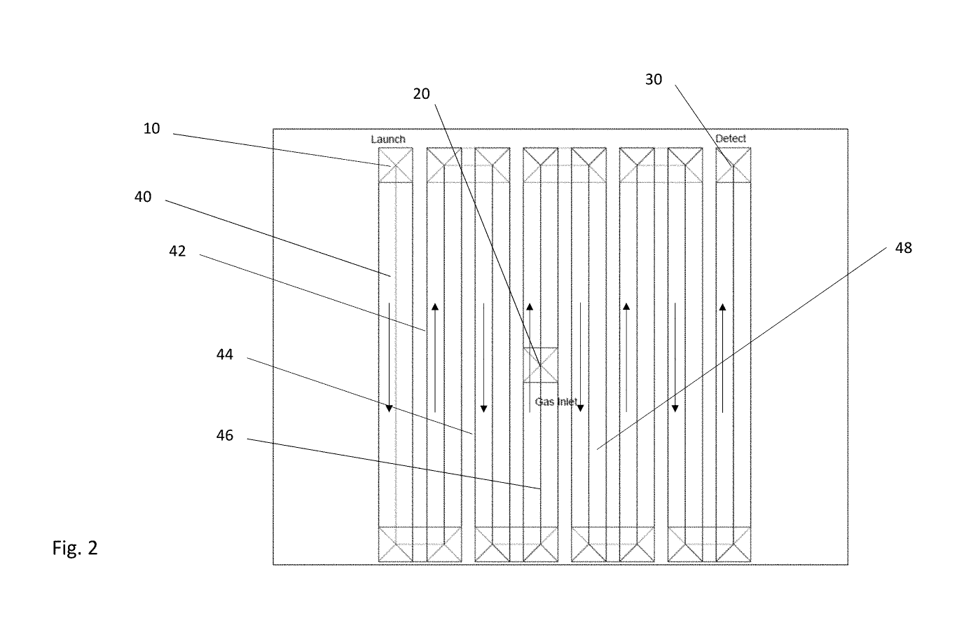

FIG. 2 shows another embodiment wherein a serpentine waveguide is formed by bonding two KOH etched Si wafers. This embodiment may provide a very long pathlength by arranging a long, narrow channel in a serpentine configuration.

As shown in FIG. 2, radiation may be emitted by the laser source 10, and injected into the first cavity 40. A cavity 40 in FIG. 2 is similar in concept to the cavity 40 in FIG. 1. It is a cavity formed by etching with the KOH etchant onto a silicon wafer. However, in FIG. 2, The multiple cavities are formed in a serpentine fashion such that the radiation first goes down cavity 40, then up cavity 42, down cavity 44, up cavity 46, etc. until the radiation finally reaches the detector 30. Reference number 20 in FIG. 2 indicates another gas inlet, which may be similar in construction to the gas inlet 20 in FIG. 1.

As before, the light emitted by laser 10 may undergo multiple reflections off of the side wall surfaces of the cavities 40-48. Each of these cavities has 54° side walls as a result of the anisotropic etching procedure. Accordingly, although the route has many turns, because of the high reflectivity of the surfaces and their 54° angle of inclination, a radiation can undergo many, many reflections without losing its amplitude. Accordingly, some fraction of the light emitted by laser 10 will be detected at detector 30, after traversing this long path lights for the serpentine layout.

Again, a substantial reduction in amplitude of transmitted light will be observed when the emission wavelength falls on an absorption feature of a target species. This reduction in amplitude as a function of wavelength will unambiguously identify the target species as being present in the sample.

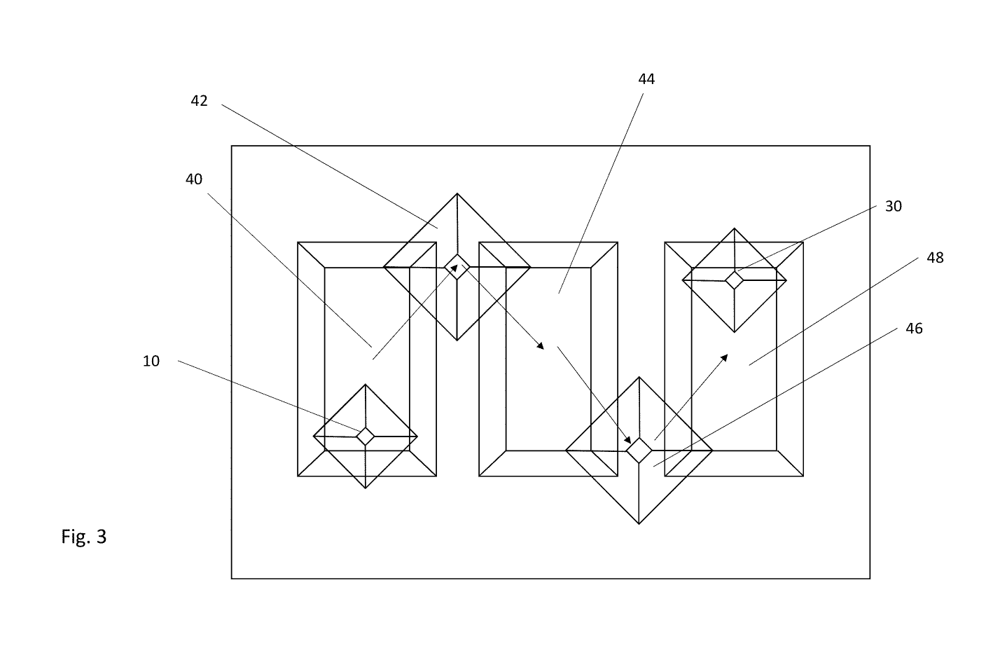

FIG. 3 is a plan view of another embodiment of the gas sensor described here. FIG. 3 shows a third embodiment, wherein a another waveguide of interconnected cavities is formed when one wafer, or at least the orientation of the cavity as formed in the wafer, is rotated with respect to the other the other. This configuration may increase the reflective scattering and thus increase the path length.

FIG. 3 is similar to FIG. 1 in that five cavities 40-48 are illustrated. Three of the cavities, 40, 44, and 48, are formed in the first substrate 100. This configuration is similar to the embodiment shown in FIG. 1. In addition to these three larger cavities, two smaller cavities 10, and 30, may also formed in the first substrate 100 or the second substrate 200 to house the emitter (10) and detector (30).

In addition to the cavities 40, 44, 48, 10 and 30 on the first substrate 100, a second substrate 200 may also have cavities from therein. Substrate 200 may have cavities 42 and 46 form therein, but cavities 42 and 46 are rotated 90 degrees with respect to cavities 40, 44 and 48. As a result of this rotation, the interconnected cavities may transmit the radiation from source 10 to detector 30 with more grazing incidence reflections. Accordingly, these smaller cavities 42 and 46 on second substrate 200 will overlap the larger cavities 40, 44 and 48 on the first substrate 100 to form an interconnected cavity path from source 10 to detector 30. It can be noted that if the cavities 10 and 30 are formed in the second substrate 200, the orientation of these cavities will be rotated in a manner similar to cavities 42 and 46 (as shown in FIG. 3).

Therefore, FIG. 3 is similar to FIG. 1 in that the plurality of cavities forms an interconnected path for a ray of light to travel from source 10 to detector 30 with multiple reflections and increases optical path length.

FIG. 4 shows a representative cross section of the waveguide with gold coated surfaces to increase the reflectance and with rays that represents the trajectory of the VCSEL radiation.

The cross sectional view of FIG. 4 is intended to be a generic cross-section of view of the interconnected cavities, illustrating how the light can traverse the interconnected cavity from source 10 to detector 30. In fact, FIG. 4 traces a particular ray of light through multiple reflections off of the 54° side walls until it finally reaching the detector 30. This ray trace is typical of many possible paths of a ray of light. It should be noticed that the cross sectional shape of the trenches 40 and 44 help to guide the light from source 10 to detector 30. The tapered trench 40 may act as a reflective surface to guide rays to the detector 30.

The distinguishing feature of these embodiments is that the rays of light will sample a large amount of the gas during their transit from source 10 to detector 30. Accordingly the interconnected cavities are an excellent way to have a long path light through the gas and in a still a compact device.

The two cavities 40 and 44 may be formed in the first substrate 100. The second cavity 42 may be formed in the second substrate 200. By overlapping cavity 42 with cavities 40 and 44, a clear path exists for the ray to traverse the cavities 40 to 42 to 44 and to the detector 30.

In the cross-sectional view a FIG. 4, the relative dimensions are readily apparent. The overall substrate sickness is about 500 microns. The overlap is about 33% of the lower cavity 42 over the upper cavities 40 and 44. This overlap is sufficient to have a channel wide enough for the ray to pass rather easily through.

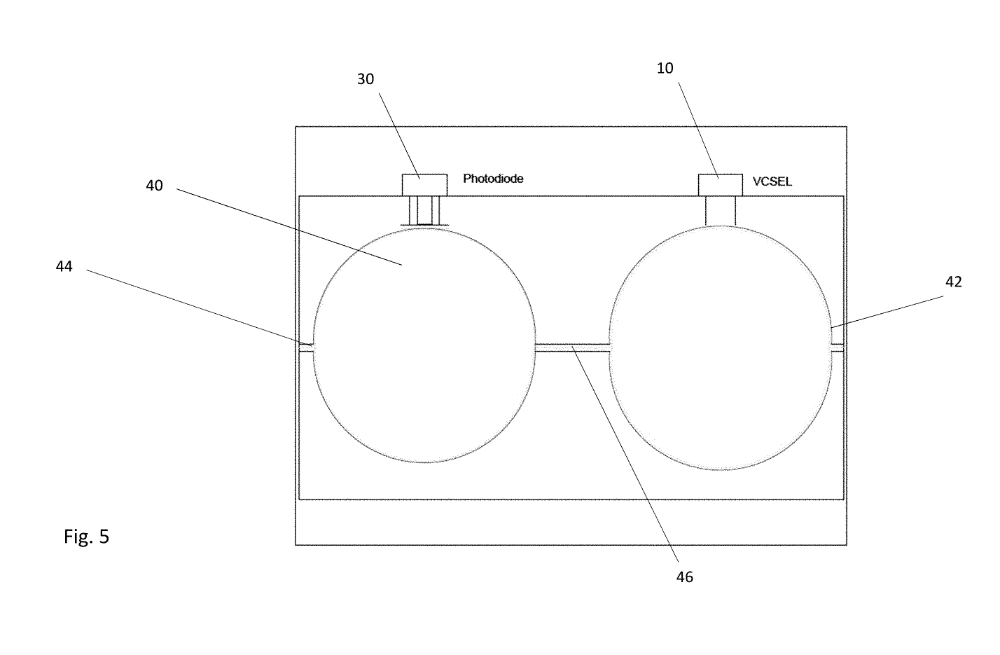

FIG. 5 shows a representative cross section of an interconnected cavity waveguide in glass, where the channels are formed with an HF etch. As is well known, glass as opposed to silicon is an amorphous, isotropic material as opposed to a crystal with crystallographic axes. Accordingly, an anisotropic etch leaving 54 degree sidewalls is not possible with glass. Hydrofluoric acid (HF) may be used to etch glass, but the etch rate is the same in all dimensions, resulting in a rounded circular hole or cylindrical channel.

Accordingly, as in the previous embodiments, the cavities in FIG. 5 may be lithographically fabricated. However, the cavities may be circular or cylindrical rather than rectilinear as in the previous silicon embodiments. Such a circular cavity maybe formed from a point hole formed in a masking layer, which allows etching of the material isotropically, away from the location of the point hole. Accordingly, this architecture is compatible with isotropic material such as glass which does not have a preferred crystallographic axis.

The etch mask may be made with a slit or a hole formed therein. The etchant is introduced through the slit or hole, and using a timed edge is allowed to remove the portion of the substrate shown in FIG. 5. The contour shown in FIG. 5 may be a cross section of a long cylindrical cavity. Although it is difficult to see in this cross-sectional view, these cylindrical cavities may form a serpentine structure similar to that shown in FIG. 2, however with rounded corners as a result of the HF isotropic etch.

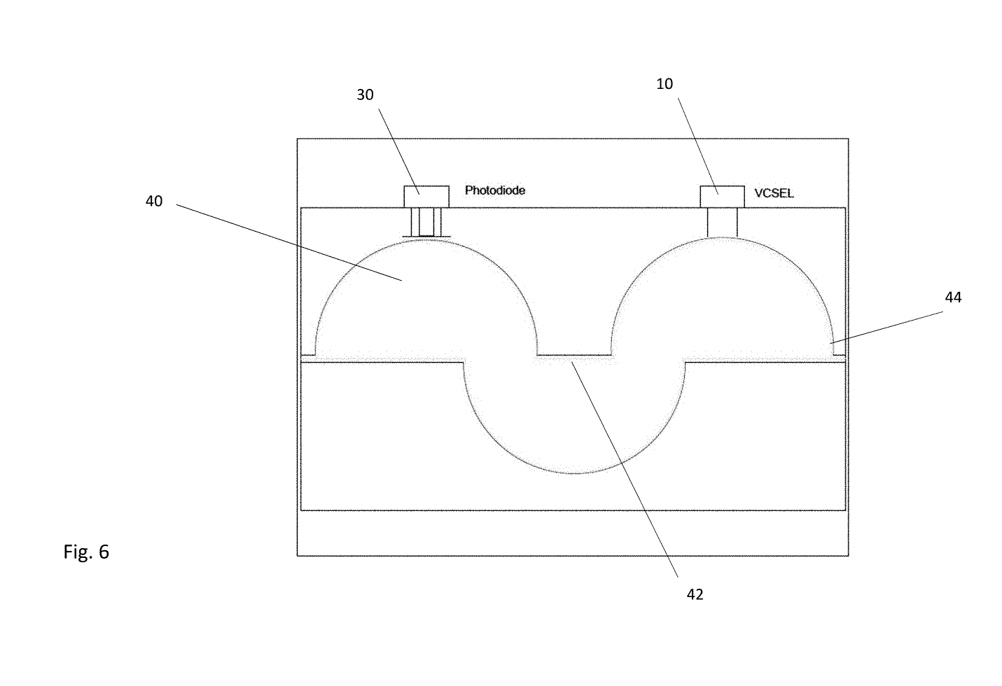

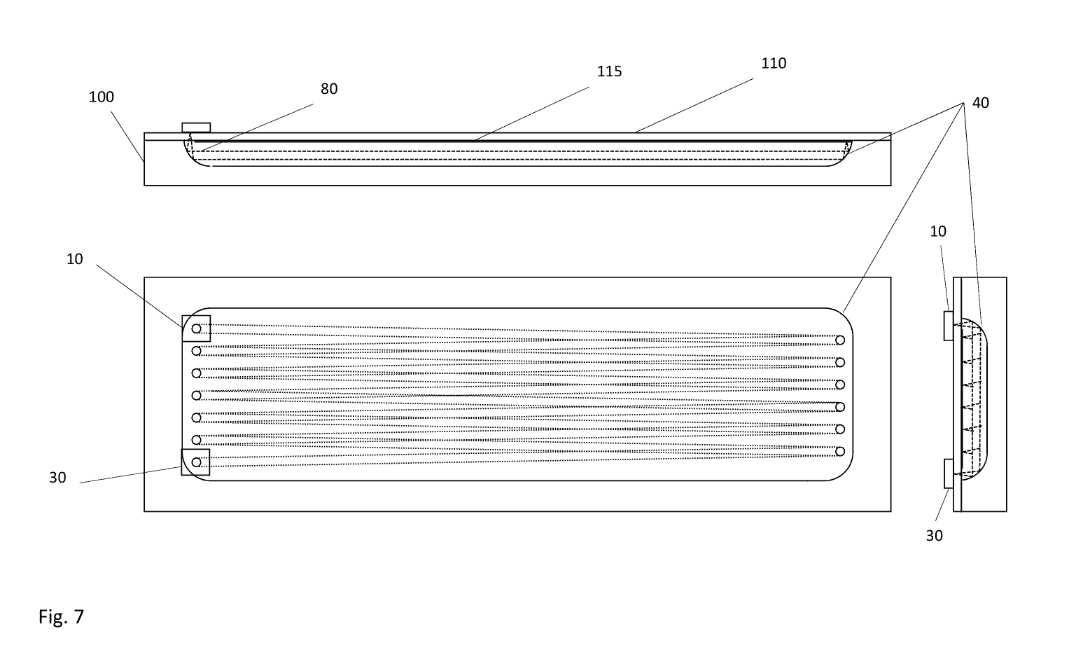

FIG. 6 shows an alternative cross section of a waveguide in glass. The channels may again be formed with an HF etch. In this embodiment, cylindrical cavities may be formed in an isotropic substrate similar to the embodiment previously shown in FIG. 5. However, in FIG. 6, the lower cavity 42 formed in the second substrate 200 may overlap the upper cavities 40, and 44 formed in the first substrate 100. This architecture is similar to that shown in FIG. 4 with the distinction that the side walls are rounded rather than angular and 54°. However, good reflections can be obtained off of these gently shaped circular side walls as well. This effect is particularly useful in the embodiment shown next in FIG. 7.

FIG. 7 shows an alternative cross section of lithographically fabricated interconnected waveguide cavities in glass. The channels may again be formed with an HF etch. In FIG. 7 are several views of this embodiment of the gas sensor are provided: FIG. 7A is the side on cross-sectional view, FIG. 7B is the plan view, and FIG. 7C is the end on cross-sectional view. In all of the views, the heavy lines 40 indicate a cavity edge, whereas the dotted lines 80 indicate a ray tracing of a route the beam of light traverses from source 10 to detector 30.

Instead of the multiple cavity configurations of the previous embodiments, the embodiment illustrated in FIG. 7 uses instead of a single long shallow cavity 40. This cavity 40 is topped with an upper layer or substrate 110, which may be relatively thin but provides a reflective surface covering the cavity 40. Light may be injected from emitter (VCSEL) 10 positioned as shown above cavity 40. Rays of light emitted from emitter (VCSEL) 10 will then undergo reflections at the smoothly contoured side of the edge cavity 40 as follows.

Considering first FIG. 7A, the cavity that is formed is generally smoothly contoured. A ray of light 80 is shown exiting the emitter 10 and bouncing off the smoothly contoured surface, from which is it is direct to the other end of the cavity. There it is reflected upward where it impinges upon the reflective film 115 deposited on the upper substrate 110. The ray of light 80 continues back and forth within the cavity 40 until finally reaching the detector 30.

The walls of the channel in each of these embodiments may be coated with a reflective film, for example gold or silver. The walls of the channel may be smoothly contoured and generally circular with respect to the bottom of the channel, as results from the isotropic etching technique. Alternatively, this embodiment may also be implemented in silicon using anisotropic KOH etching, in which case the sidewalls will have an inclination of 54 degrees. Light directed upward by the 54 degree sidewalls will be reflected by into the cavity 40 by the upper reflective surface 115 on layer 110.

FIG. 8 shows a typical infrared spectrum of the atmosphere in the region of CO₂. Note that the very weak absorption lines that are interspersed with the stronger lines are absorption due to ¹³CO₂, where the ¹³C has a natural abundance of ˜1%. This provides further safeguard against false assignment. Using the gas sensor described above, the VCSEL may be tuned through a wavelength range and across an absorption feature shown in FIG. 8. When the wavelength is at the center of the absorption feature at, for example, 2331 wavenumbers, a strong attenuation of the signal at the detector would be observed if CO₂ is present in the gas sample.

Accordingly, a gas sensing device is described. The gas sensor may include at least one substrate with gas channels formed lithographically therein, and with a reflective film coating the walls, a sample gas filling the lithographically formed channels, a radiation source coupled to the at least one substrate that launches radiation into the lithographically formed channels, and a detector coupled to the at least one substrate, that detects radiation transmitting the lithographically formed channels. The at least one substrate may comprise at least two substrates, wherein the substrates are arranged in a staggered fashion and bonded together to form a longer lithographically formed channel.

The longer lithographically formed channel may be in the shape of a serpentine, with gas filled from a portion of the longer lithographically formed channel in one. The lithographically formed channel may have sidewalls with an incline of between 40 and 60 degrees, and created by the etching of the channel with a liquid anisotropic etchant. The walls of the channel may be coated with a reflective film, which may be gold. The longer lithographically formed channel may be either cylindrical or trapezoidal in cross section, and may be formed by at least one of KOH and HF.

A method of measuring a gas sample is also disclosed. The method may comprise filling a lithographically formed gas channel with a sample gas, wherein the channel is formed by bonding at least two substrates, wherein the substrates are arranged in a staggered fashion and bonded together to form a longer lithographically formed channel, launching radiation from a VCSEL down the lithographically formed gas channel, and detecting the radiation after transmitting the lithographically formed channel.

Within the method, the longer lithographically formed channel may be in the shape of a serpentine, with gas filled from a portion of the longer lithographically formed channel in one. The lithographically formed channel may have sidewalls with an incline of between 40 and 60 degrees, and created by the etching of the channel with a liquid anisotropic etchant. The walls of the channel may be coated with a reflective film, which may be gold.

The longer lithographically formed channel may be either cylindrical or trapezoidal. The lithographically formed channels may be formed by at least one of KOH and HF.

Also disclosed is a method of manufacturing a gas sensor. The method may comprise bonding at least two substrates, wherein the substrates are arranged in a staggered fashion and bonded together to form a longer lithographically formed channel, coating the channels with a reflective film, coupling a VCSEL source to the reflective channel, and coupling a detector to the reflective channel. The longer lithographically formed channel may be in the shape of a serpentine, with gas filled from a portion of the longer lithographically formed channel in one. The lithographically formed channel may have sidewalls with an incline of between 40 and 60 degrees, and created by the etching of the channel with a liquid anisotropic etchant. The walls of the channel may be coated with a reflective film, which may be gold.

The longer lithographically formed channel may be either circular or spherical. The lithographically formed channels may be formed by at least one of KOH and HF.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. Furthermore, although the embodiment described herein pertains primarily to an electrical switch, it should be understood that various other devices may be used with the systems and methods described herein. Accordingly, the exemplary implementations set forth above, are intended to be illustrative, not limiting.

What is claimed is:

1. A gas sensing device, comprising:
at least one substrate with at least one cavity cavities formed lithographically therein, and with a reflective film coating sidewalls of the at least one cavity, and wherein the at least one cavity is configured for multiple passes of a ray of light within the cavity
a sample gas filling the lithographically formed cavities;
a radiation source coupled to the at least one substrate that launches radiation into the lithographically formed channels ; and
a detector coupled to the at least one substrate, that detects radiation transmitting the lithographically formed cavities.

2. The gas sensing device of claim 1, wherein the at least one substrate comprises at least two substrates with at least one cavity formed on each substrate, and wherein the substrates are arranged such that the cavities partly overlap and form passages that interconnect, to form a longer optical path through the interconnected cavities.

3. The gas sensing device of claim 2, wherein the longer lithographically formed cavity is in the shape of a serpentine channel, with radiation transiting from source to detector along the serpentine channel.

4. The gas sensing device of claim 2, wherein the lithographically formed channel has sidewalls with an incline of between 40 and 60 degrees, and created by the etching of the channel with a liquid anisotropic etchant and wherein the etchant is at least one of KOH and HF

5. The gas sensor of claim 2, wherein walls of the channel are coated with a reflective film.

6. The gas sensor of claim 5, wherein the reflective film is gold.

7. The gas sensor of claim 3, wherein the longer lithographically formed channel is either cylindrical or trapezoidal in cross section.

8. A method of measuring a gas sample, comprising
Filling a lithographically formed gas channel with a sample gas, wherein the channel is formed by bonding at least two substrates, wherein the substrates are arranged in a staggered fashion and bonded together to form a longer lithographically formed channel;
launching radiation from a VCSEL down the lithographically formed gas channel; and
detecting the radiation after transiting the lithographically formed channel.

9. The method of claim 9, wherein the longer lithographically formed channel is in the shape of a serpentine, with gas flowing from a portion of the longer lithographically formed channel in one

10. The method of claim 9, wherein the lithographically formed channel has sidewalls with an incline of between 40 and 60 degrees, and created by the etching of the channel with a liquid etchant, wherein the etchant is at least one of KOH and HF.

11. The method of claim 9, wherein walls of the channel are coated with a gold reflective film.

12. The method of claim 9, wherein the longer lithographically formed channel is either cylindrical or trapezoidal.

13. The method of claim 9, wherein the lithographically formed channels are formed by at least one of KOH and HF.

14. A method of manufacturing a gas sensor, comprising:
bonding at least two substrates, wherein the substrates are arranged in a staggered fashion and bonded together to form a longer lithographically formed channel;
coating the channels with a reflective film;
coupling a VCSEL source to the reflective channel; and
coupling a detector to the reflective channel.

15. The method of claim 14, wherein the longer lithographically formed channel is in the shape of a serpentine, with gas flowing from a portion of the longer lithographically formed channel in one

16. The method of claim 14, wherein the lithographically formed channel has sidewalls with an incline of between 40 and 60 degrees, and created by the etching of the channel with a liquid anisotropic etchant.

17. The method of claim 14, wherein walls of the channel are coated with a reflective film.

18. The method of claim 14, wherein the reflective film is gold.

19. The method of claim 14, wherein the longer lithographically formed channel is either cylindrical or trapezoidal..

20. The method of claim 14, wherein the lithographically formed channels are formed by at least one of KOH and HF.
